(19) United States
(12) Patent Application Publication
(10) Pub. No.: US 2024/0028297 A1
(43) Pub. Date: Jan. 25, 2024

(54) SEMICONDUCTOR DEVICE PERFORMING A MULTIPLICATION AND ACCUMULATION OPERATION

(71) Applicants: SK HYNIX Inc., Icheon (KR); Korea Advanced Institute of Science and Technology, Daejeon (KR)

(72) Inventors: Kyunghyun KIM, Daejeon (KR); Seonghwan CHO, Daejeon (KR)

(21) Appl. No.: 18/148,161

(22) Filed: Dec. 29, 2022

(30) Foreign Application Priority Data
Jul. 25, 2022 (KR) 1020220091487

(51) Int. Cl. G06F 7/544; G06N 3/063

(52) U.S. Cl. CPC G06F 7/5443; G06N 3/063

(57) ABSTRACT

A semiconductor device includes a memory cell array including a plurality of memory cells coupled between a plurality of word lines and a plurality of bit lines; and a computing circuit configured to perform a multiplication and accumulation (MAC) operation using a plurality of input data and a plurality of weights respectively provided from the plurality of bit lines, wherein one or more memory cells connected to each of the plurality of bit lines store a corresponding one of the plurality of weights, and the one or more memory cells store sign information of the corresponding weight.

### CROSS-REFERENCE TO RELATED APPLICATION

The present application claims priority under 35 U.S.C. § 119(a) to Korean Patent Application No. 10-2022-0091487, filed on Jul. 25, 2022, which is incorporated herein by reference in its entirety.

### BACKGROUND

### 1. Technical Field

Various embodiments relate to a semiconductor device capable of performing a multiplication and accumulation (MAC) operation, and more particularly, to a semiconductor device capable of performing a MAC operation supporting a negative weight.

### 2. Related Art

Neural networks are widely used in artificial intelligence applications such as image recognition and technologies used in autonomous vehicles.

For example, a neural network includes an input layer, an output layer, and one or more inner layers between the input layer and the output layer.

Each of the output layer, the input layer, and the inner layers includes one or more neurons. Neurons contained in adjacent layers are connected in various ways through synapses. For example, synapses point from neurons in a given layer to neurons in a next layer. Alternately or additionally, synapses point to neurons in a given layer from neurons in a preceding layer.

Each of the neurons stores a value. The values of the neurons included in the input layer are determined according to an input signal, for example, an image to be recognized. The values of the neurons contained in the inner and the output layers are determined based on the neurons and the synapses contained in corresponding preceding layers. For example, the values of the neurons in each of the inner layers are determined based on the values of the neurons in a preceding layer in the neural network.

Each of the synapses has a weight. The weight of each of the synapses is determined by training the neural network.

After the neural network is trained, the neural network can be used to perform an inference operation. In the inference operation, the values of the neurons in the input layer are set based on the input signal, and the values of the neurons in the next layers (e.g., the inner layers and the output layer) are set based on the values of the neurons in the input layer and the weights of the synapses connecting the layers. The values of the neurons in the output layer represent a result of the inference operation.

For example, in the inference operation, in which image recognition is performed by the neural network after the neural network has been trained, the values of the neurons in the input layer are set based on an input image, a plurality of operations are performed at the inner layers based on the values of the neurons in the input layer, and a result of the image recognition is output at the output layer from the inner layers.

In such an inference operation, a large number of MAC operations must be performed by neurons in a convolutional neural network. Therefore, a semiconductor device that can efficiently perform the large number of MAC operations is desired.

The conventional memory device for performing MAC operations has a structure that significantly deforms the existing memory structure, and thus memory performance is deteriorated and an area and power consumption are increased.

In addition, the conventional memory device cannot support various neural network operations because it cannot process negative weights.

### SUMMARY

In accordance with an embodiment of the present disclosure, a semiconductor device may include a memory cell array including a plurality of memory cells coupled between a plurality of word lines and a plurality of bit lines; and a computing circuit configured to perform a multiplication and accumulation (MAC) operation using a plurality of input data and a plurality of weights respectively provided from the plurality of bit lines, wherein one or more memory cells connected to each of the plurality of bit lines store a corresponding one of the plurality of weights, and the one or more memory cells store sign information of the corresponding weight.

### BRIEF DESCRIPTION OF THE DRAWINGS

The accompanying figures, wherein like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates a semiconductor memory device according to an embodiment of the present disclosure.

FIG. 2 illustrates a computing circuit according to an embodiment of the present disclosure.

FIG. 3 illustrates a unit computing circuit according to an embodiment of the present disclosure.

FIG. 4 is a timing diagram illustrating an operation of a semiconductor device according to an embodiment of the present disclosure.

FIG. 5 illustrates a computing circuit according to another embodiment of the present disclosure.

FIG. 6 illustrates a unit computing circuit according to another embodiment of the present disclosure.

FIG. 7 is a timing diagram illustrating an operation of a semiconductor device according to another embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

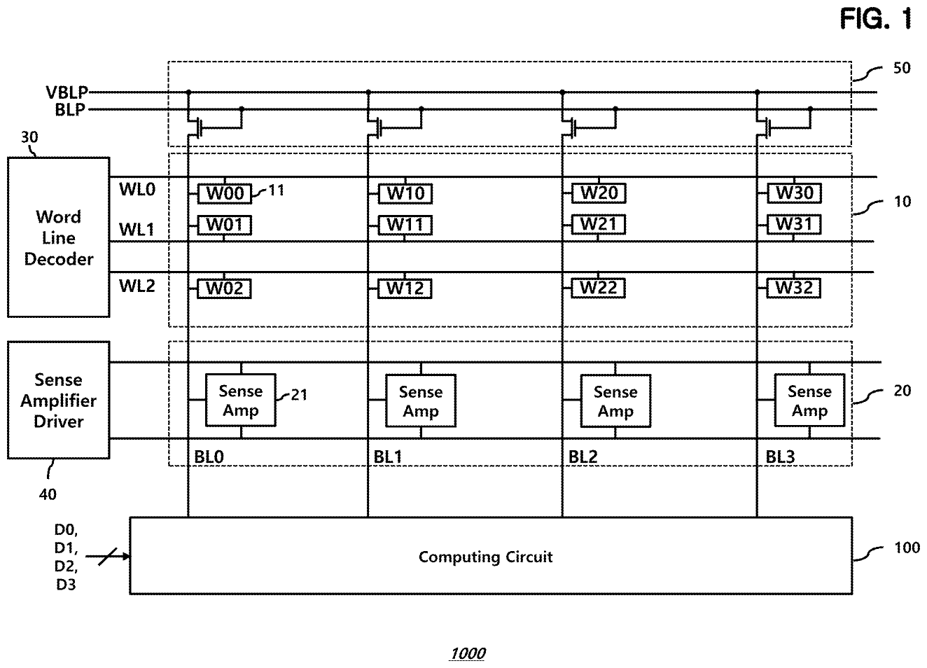

FIG. 1 illustrates a semiconductor device 1000 according to an embodiment of the present disclosure.

Referring to FIG. 1, the semiconductor device 1000 includes a memory cell array 10, a sense amplifier array 20, a word line decoder a sense amplifier driver 40, a bit line precharge circuit 50, and a computing circuit 100.

The memory cell array 10 includes a plurality of word lines, e.g., WL0 to WL2, a plurality of bit lines, e.g., BL0 to BL3, and a plurality of memory cells 11 connected between the plurality of word lines WL0 to WL2 and the plurality of bit lines BL0 to BL3.

Each of the plurality of memory cells 11 stores a weight bit.

Each of the plurality of memory cells 11 may be a volatile memory cell, such as a DRAM cell or an SRAM cell, or a nonvolatile memory cell, such as a flash memory cell or a resistive memory cell, but embodiments are not limited to a specific type of cell.

Data stored in a set of memory cells 11 connected to one bit line may correspond to a multi-bit weight.

For example, the three memory cells connected to the 0th bit line BL0 store 3 bits of a 0th weight W0. The 0th weight W0 includes a 0th weight bit W00, a 1st weight bit W01, and a 2nd weight bit W02. The three memory cells connected to the 1st bit line BL1 store 3 bits of a first weight W1. The 1st weight W1 includes a 0th weight bit W10, a 1st weight bit W11, and a 2nd weight bit W12. The three memory cells connected to the 2nd bit line BL2 store 3 bits of a second weight W2. The 2nd weight W2 includes a 0th weight bit W20, a 1st weight bit W21, and a 2nd weight bit W22. The three memory cells connected to the 3rd bit line BL3 store 3 bits of a third weight W3. The 3rd weight W3 includes a 0th weight bit W30, a 1st weight bit W31, and a 2nd weight bit W32.

More specifically, among the three memory cells connected to the 0th bit line BL0, the memory cell connected to the 0th word line WL0 stores the 0th weight bit W00 of the 0th weight W0, the memory cell connected to the 1st word line WL1 stores the 1st weight bit W01 of the 0th weight W0, and the memory cell connected to the 2nd word line WL2 stores the 2nd weight bit W02 of the 0th weight W0. The 2nd weight bit W02 may be used as a sign bit.

The sense amplifier array 20 includes a plurality of sense amplifiers (Sense Amp) 21 for determining data stored in the plurality of memory cells 11 by amplifying signals of the plurality of bit lines BL0 to BL3.

The word line decoder 30 controls the plurality of word lines WL0 to WL2, and the sense amplifier driver 40 controls the plurality of sense amplifiers 21.

Since the configuration and operation of the memory cell array 10, the sense amplifier array 20, the word line decoder 30, and the sense amplifier driver 40 are well known from a conventional semiconductor device, a detailed description thereof will be omitted.

The bit line precharge circuit 50 precharges the plurality of bit lines BL0 to BL3 to a precharge voltage VBLP in response to a bit line precharge signal BLP.

The weights W0 to W3 may be provided to the computing circuit 100 through the plurality of bit lines BL0 to BL3, respectively.

The computing circuit 100 performs a multiplication and accumulation (MAC) operation using input data D0 to D3 and the weights W0 to W3.

In this embodiment, the input data D0 to D3 and the weights W0 to W3 are multi-bit digital signals.

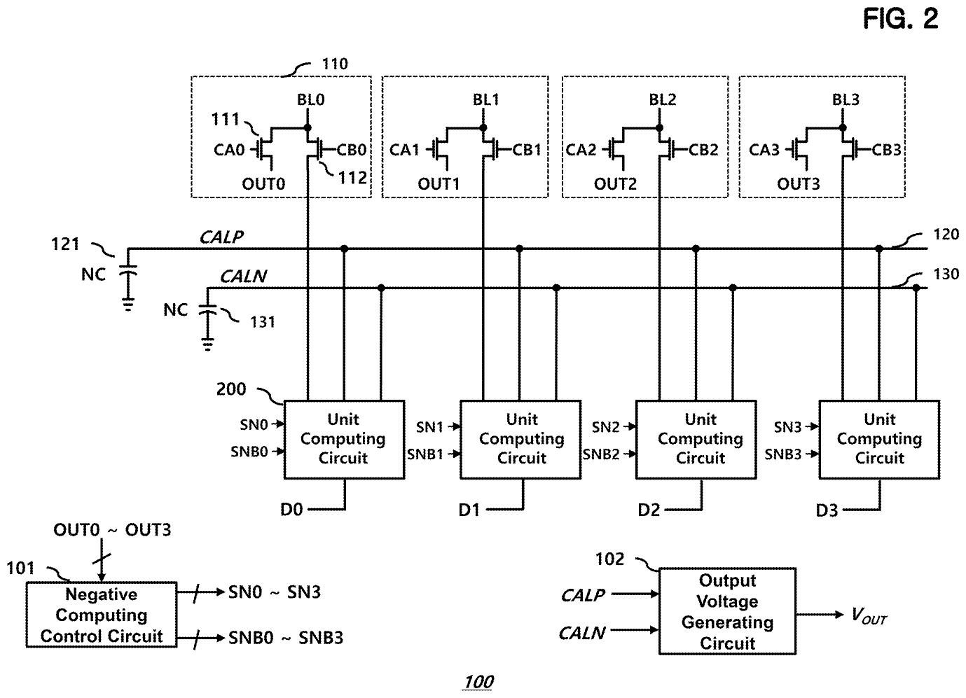

FIG. 2 illustrates a computing circuit 100 according to an embodiment of the present disclosure. The computing circuit 100 shown in FIG. 2 may correspond to the computing circuit 100 of FIG. 1.

Referring to FIG. 2, the computing circuit 100 includes a plurality of bit line connection circuits 110, a first common line 120, a first common capacitor 121, a second common line 130, a second common capacitor 131, and a plurality of unit computing circuits 200.

The bit line connection circuits 110 all have the same configuration. Each of the bit line connection circuits 110 connects a bit line and a corresponding one of the unit computing circuits 200.

For example, the bit line connection circuit 110 connected to the bit line BL0 includes a switch 111 that converts a signal of the bit line BL0, which can be referred to as a bit line signal BL0, to an output signal OUT0 in response to a control signal CA0, and a switch 112 that provides the bit line signal BL0 to the corresponding unit computing circuit 200 in response to a control signal CB0.

One terminal of the first common capacitor 121 is connected to the first common line 120 and the other terminal of the first common capacitor 121 is grounded. A voltage of the first common line 120 is referred to as a first common voltage CALP.

In this embodiment, a capacitance of the first common capacitor 121 is expressed as NC. In this case, N corresponds to the number of weights used in the calculation, that is, the number of bit lines, and has a value of 4 in the present disclosure.

One terminal of the second common capacitor 131 is connected to the second common line 130 and the other terminal is grounded. A voltage of the second common line 130 is referred to as a second common voltage CALN.

In this embodiment, a capacitance of the second common capacitor 131 is expressed as NC. As described above, in the present disclosure, N is 4.

The plurality of unit computing circuits 200 all have the same configuration and perform computing operations using weights and corresponding input data.

The unit computing circuit 200 corresponding to the bit line BL0 is connected to the bit line BL0, the first common line 120, and the second common line 130, and receives input data D0.

The computing circuit 100 further includes a negative computing control circuit 101 and an output voltage generating circuit 102. The negative computing control circuit 101 generates first sign signals SN0 to SN3 and second sign signals SNB0 to SNB3 based on the output signals OUT0 to OUT3. The first sign signals SN0 to SN3 and the second sign signals SNB0 to SNB3 are provided to the unit computing circuits 200, respectively. For example, the first sign signal SN0 and the second sign signal SNB0 are provided to the unit computing circuit 200 corresponding to the bit line BL0, and the first sign signal SN3 and the second sign signal SNB3 are provided to the unit computing circuit 200 corresponding to the bit line BL3.

In this case, the output signals OUT0 to OUT3 are data signals corresponding to sign bits and are output by performing a sign read operation, and the sign read operation may be performed in advance at the beginning of the computing operation.

The unit computing circuit 200 corresponding to the bit line BL0 performs the computing operation in response to the first sign signal SN0 and the second sign signal SNB0 provided by the negative computing control circuit 101.

In this embodiment, the sign bit is output from a memory cell connected to a second word line, e.g., WL2 shown in FIG. 1.

Accordingly, during the sign read operation, most significant bits, e.g., W02, W12, W22, and W32 shown in FIG. 1, of the weights are output as the output signals OUT0, OUT1, OUT2, and OUT3, respectively.

During the sign read operation, the switch 111 of the bit line connection circuit 110 is turned on to provide the output signal, e.g., OUT0, to the negative computing control circuit 101.

In the present embodiment, when the output signal OUT0 has a low level corresponding to a positive weight, the negative computing control circuit 101 sets the first sign signal SN0 to the low level and the second sign signal SNB0 to the high level. On the other hand, when the output signal OUT0 has a high level corresponding to a negative weight, the negative computing control circuit 101 sets the first sign signal SN0 to the high level and the second sign signal SNB0 to the low level.

The above sign read operation can be also applied to the other bit lines BL1 to BL3 to provide the output signals OUT1 to OUT3, the first sign signals SN1 to SN3, and the second sign signal SNB1 to SNB3.

The output voltage generating circuit 102 outputs an output voltage V_{OUT} based on the first common voltage CALP and the second common voltage CALN.

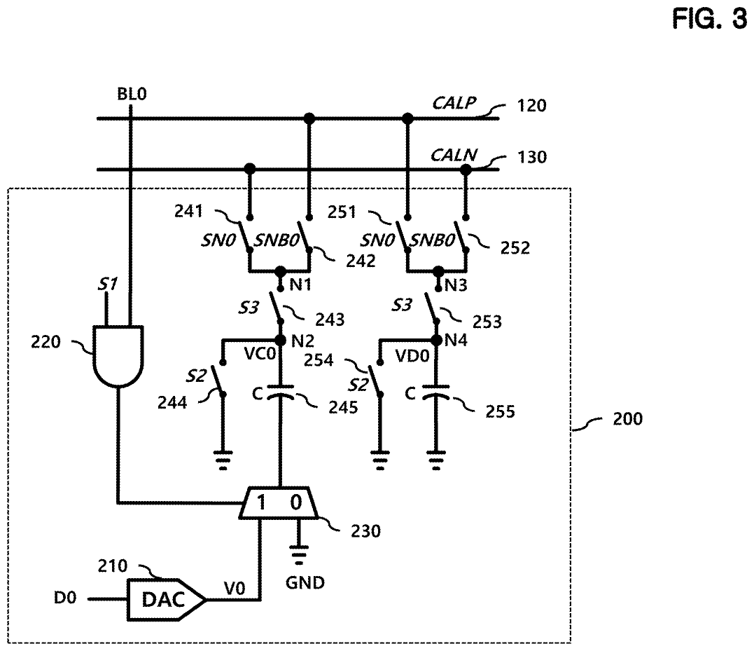

FIG. 3 illustrates the unit computing circuit 200 of FIG. 2 according to an embodiment of the present disclosure.

The unit computing circuit 200 includes a digital-to-analog converter (DAC) 210 for converting the input data D0 into an analog input voltage V0, an AND gate 220 for performing an AND operation on a first signal S1 and the bit line signal BL0, and a selection circuit 230 for selecting the input voltage V0 or the ground voltage GND according to an output of the AND gate 220.

The unit computing circuit 200 further includes a switch 241 connected between the second common line 130 and a first node N1, a switch 242 connected between the first common line 120 and the first node N1, a switch 243 connected between the first node N1 and a second node N2, a switch 244 connected between the second node N2 and a ground node GND, and a first capacitor 245 connected between an output terminal of the selection circuit 230 and the second node N2.

The unit computing circuit 200 further includes a switch 251 connected between the first common line 120 and a third node N3, a switch 252 connected between the second common line 130 and the third node N3, a switch 253 connected between the third node N3 and a fourth node N4, a switch 254 connected between the fourth node N4 and the ground node GND, and a second capacitor 255 connected between the fourth node N4 and the ground node GND.

The switches 241 and 251 are controlled according to the first sign signal SN0, the switches 242 and 252 are controlled according to the second sign signal SNB0, and the switches 244 and 254 are controlled according to a second signal S2, and the switches 243 and 253 are controlled according to a third signal S3.

As described above, in the 0th weight W0 including the 0th weight bit W00, the 1st weight bit W01, and the 2nd weight bit W02, the 2nd weight bit W02 is a sign bit, and the 1st weight bit W01 and the 0th weight bit W00 are magnitude bits. The magnitude bits are read out sequentially from the least significant bit W00 to the most significant bit W01. When the sign bit W02 is 0, it is a positive number, and when the sign bit W02 is 1, it is a negative number.

Hereinafter, a negative number calculation method will be described with reference to FIGS. 1 to 4.

In this embodiment, it is assumed that the 0th weight W0 is +3 (011), the 1st weight W1 is +2 (010), the 2nd weight W2 is −2 (110), and the 3rd weight W3 is −1 (101).

Also, it is assumed that the input voltage V0 corresponding to the input data D0 is 500 mV, an input voltage V1 corresponding to the input data D1 is 700 mV, an input voltage V2 corresponding to the input data D2 is 400 mV, and an input voltage V3 corresponding to the input data D3 is 200 mV.

Also, it is assumed that the sign read operation is performed in advance to determine the first sign signals SN0 to SN3 and the second sign signals SNB0 to SNB3.

Since the 0th weight W0 and the 1st weight W1 have the positive number, their output signals OUT0 and OUT1 each have the low level. Therefore, the first sign signals SN0 and SN1 respectively corresponding to the 0th weight W0 and the 1st weight W1 are set to the low level, and the second sign signals SNB0 and SNB1 are set to the high level.

On the other hand, since the 2nd weight W2 and the 3rd weight W3 have the negative number, their output signals OUT2 and OUT3 each have the high level. Therefore, the first sign signals SN2 and SN3 respectively corresponding to the 2nd weight W2 and the 3rd weight W3 are set to the high level, and the second sign signals SNB2 and SNB3 are set to the low level.

Accordingly, referring to FIG. 3, the switches 241 and 251 are turned off and the switches 242 and 252 are turned on, so that the first common line 120 is connected to the switch 243 and the second common line 130 is connected to the switch 253.

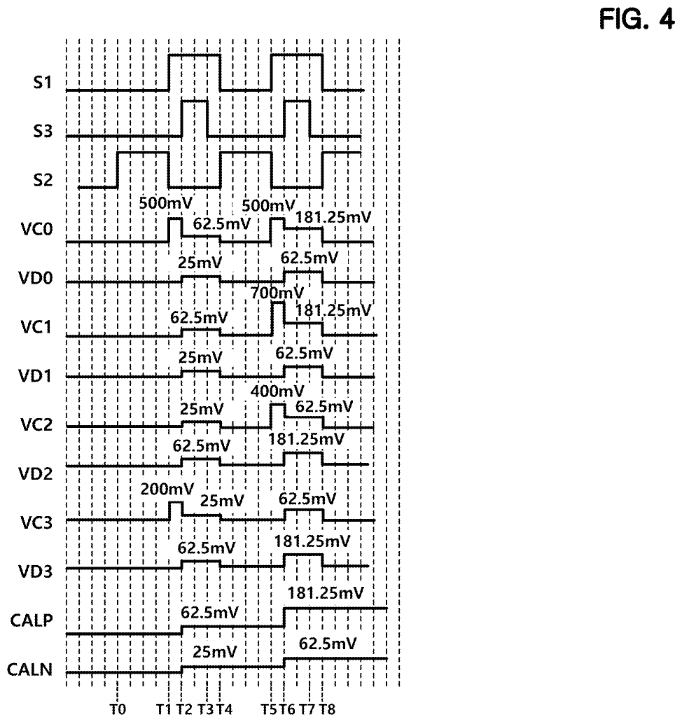

Referring to FIG. 4, a reset operation is performed in a time period of T0 to T1.

During the reset operation, the first signal S1 is set to the low level, the second signal S2 is set to the high level, and the third signal S3 is set to the low level.

Accordingly, the output of the AND gate 220 is at the low level and the switches 244 and 254 are turned on, so that the first capacitor 245 and the second capacitor 255 are discharged.

An operation performed in a time period of T1 to T4 corresponds to a read operation of the 0th weight bits W00, W10, W20, and W30 and a computing operation thereof.

In a time period of T1 to T2, the first signal S1 is set to the high level, the second signal S2 is set to the low level, and the third signal S3 is set to the low level, and a corresponding input voltage or the ground voltage GND is provided to the first capacitor 245 according to a corresponding bit line signal.

In FIG. 3, “1” corresponding to the 0th weight bit W00 is output from the bit line BL0, so 500 mV of the input voltage V0 is input to the first capacitor 245 and a voltage VC0 of the second node N2 becomes 500 mV and a voltage VD0 of the fourth node N4 is maintained at 0V because the switches 244, 243, 254, and 253 are in a floating state.

In the same manner, since the bit line BL3 outputs “1” corresponding to the 0th weight bit W30 and the input voltage V3 is 200 mV, a node voltage VC3 becomes 200 mV, and a node voltage VD3 is maintained at 0V.

Since “0” corresponding to the 0th weight bits W10 and W20 is output from the bit lines BL1 and BL2, node voltages VC1 and VC2 become 0V regardless of the input voltages V1 and V2, and node voltages VD1 and VD2 are maintained at 0V.

In a time period of T2 to T3, an analog computing operation corresponding to the 0th weight bits is performed.

In the time period of T2 to T3, the third signal S3 is changed to the high level, and accordingly, the switches 243 and 253 are turned on.

As described above, since the 0th weight W0 has a positive value, the first sign signal SN0 is set to the low level and the second sign signal SNB0 is set to the high level, so that the first capacitor 245 is connected to the first common line 120 and the second capacitor 255 is connected to the second common line 130.

Similarly, since the 1st weight W1 has a positive value, a corresponding first capacitor is connected to the first common line 120, and a corresponding second capacitor is connected to the second common line 130.

Since the 2nd weight W2 and the 3rd weight W3 have negative values, their corresponding first capacitors are connected to the second common line 130, and their corresponding second capacitors are connected to the first common line 120.

The first common line 120 is connected to the first common capacitor 121 whose capacitance is NC (=N×C), and the second common line 130 is connected to the second common capacitor 131 whose capacitance is NC (=N×C), C being a capacitance of each of the first capacitor 245 and the second capacitor 255. In this embodiment, N is 4.

When the law of conservation of charge is applied, as a result of the computing operation for the 0th weight bits W00, W10, W20, and W30 during the time period of T2 to T3, the first common voltage CALP is calculated as shown in Equation 1, and the second common voltage CALN is calculated as shown in Equation 2.

$$\begin{matrix}CALP = \frac{500 mV \times 1 + 700 mV \times 0}{8} = 62.5 mV & [ Equation 1 ] \\ CALN = \frac{400 mV \times 0 + 200 mV \times 1}{8} = 25 mV & [ Equation 2 ]\end{matrix}$$

During the read operation, since, in each unit computing circuit 200, each of the first capacitor 245 and the second capacitor 255 is connected to one of the first common line 120 and the second common line 130 according to a value of a corresponding bit line signal, each of the node voltages VCi and VDi has the same voltage level as one of the first common voltage CALP and the second common voltage CALN, i being in a range of 0 to 2.

In a time period of T3 to T4, the third signal S3 is changed to the low level to separate the first common line 120 and the second common line 130 from the unit computing circuit 200. In the time period of T3 to T4, the node voltages VCi and VDi maintain their voltage levels obtained in the time period of T2 to T3.

The reset operation is performed again in a time period of T4 to T5.

In the reset operation, since at least the second signal S2 is at the high level, both the first capacitor 245 and the second capacitor 255 in the unit computing circuit 200 are discharged as being grounded.

An operation performed in a time period of T5 to T8 corresponds to a read operation and a computing operation corresponding to the 1st weight bits W01, W11, W21, and W31.

In a time period of T5 to T6, the first signal S1 is set to the high level, the second signal S2 is set to the low level, and the third signal S3 is set to the low level, and a corresponding input voltage or the ground voltage GND is applied to the first capacitor 245 according to a corresponding bit line signal.

In FIG. 3, “1” corresponding to the 1st weight bit W01 is output from the bit line BL0, so 500 mV of the input voltage V0 is input to the first capacitor 245, and the switches 243, 244, 253, and 254 are in a floating state. Therefore, the voltage VC0 of the second node N2 becomes 500 mV, and the voltage VD0 of the fourth node N4 is maintained at 0V.

Because “1” corresponding to the 1st weight bit W11 is output from the bit line BL1 and the input voltage V1 is 700 mV, the node voltage VC1 becomes 700 mV, and the node voltage VD1 is maintained at 0 V.

Because “1” is output from the bit line BL2 corresponding to the 1st weight bit W21 and the input voltage V2 is 400 mV, the node voltage VC2 becomes 400 mV, and the node voltage VD2 is maintained at 0 V.

Because “0” is output from the bit line BL3 corresponding to the 1st weight bit W31 and the input voltage V3 is 200 mV, the node voltage VC3 becomes 0V, and the node voltage VD2 is maintained at 0V.

In a time period of T6 to T7, an analog computing operation corresponding to the 1st weight bits W01, W11, W21, and W31 is performed.

In the time period of T6 to T7, the third signal S3 is at the high level, and accordingly, the switches 243 and 253 are turned on.

As described above, since the 0th weight W0 and the 1st weight W1 have positive values, the corresponding first capacitors 245 are connected to the first common line 120, and the corresponding second capacitors 255 are connected to the second common line 130.

Since the 2nd weight W2 and the 3rd weight W3 have negative values, the corresponding first capacitors 245 are connected to the second common line 130, and the corresponding second capacitors 255 are connected to the first common line 120.

The first common line 120 is connected to the first common capacitor 121, and the second common line 130 is connected to the second common capacitor 131.

When the law of conservation of charge is applied, as a result of the computing operation for the 1st weight bits W01, W11, W21, and W31 during the time period of T6 to T7, the first common voltage CALP is calculated as shown in Equation 3, and the second common voltage CALN is calculated as shown in Equation 4.

$$\begin{matrix}CALP = \frac{500 mV \times 1 + 700 mV \times 0}{16} + \frac{500 mV \times 1 + 700 mV \times 0}{8} = 181.25 mV & [ Equation 3 ] \\ CALN = \frac{400 mV \times 0 + 200 mV \times 1}{16} + \frac{400 mV \times 0 + 200 mV \times 1}{8} = 62.5 mV & [ Equation 4 ]\end{matrix}$$

The first common voltage CALP stores a MAC operation result corresponding to a positive weight, and the second common voltage CALN stores a MAC operation result corresponding to a negative weight.

The first common voltage CALP and the second common voltage CALN may be generally represented by Equation 5 and Equation 6, respectively.

$$\begin{matrix}CALP = \frac{1}{N \times {2}^{M}} {\sum }_{j = 0}^{M - 1} {\sum }_{i = 0}^{N - 1} {V}_{i} {W}_{i , j} {w}^{j} {X}_{i} & [ Equation 5 ] \\ CALN = \frac{1}{N \times {2}^{M}} {\sum }_{j = 0}^{M - 1} {\sum }_{i = 0}^{N - 1} {V}_{i} {W}_{i , j} {w}^{j} {Y}_{i} & [ Equation 6 ]\end{matrix}$$

In Equation 5, Xᵢ is 1 if an i-th weight is positive, otherwise Xi is 0. In Equation 6, Yᵢ is 1 if the i-th weight is negative, and otherwise Yi is 0. In Equations 5 and 6, Vᵢ represents a corresponding input voltage, W_{i,j} represents a value of a corresponding weight bit. For example, Vᵢ corresponds to one of the input voltages V0, V1, V2, and V3, and W_{i,j} corresponds to one of the weight bits W00, W01, W02, W10, W11, W12, W20, W21, W22, W30, W31, and W32.

N corresponds to the number of unit computing circuits, that is, the number of elements of an input data vector or a weight vector, and M corresponds to the number of weight bits in the weight excluding a sign bit. In the embodiment, N is 4 and M is 2.

Referring back to FIG. 2, the output voltage generating circuit 102 generates the output voltage V_{OUT} corresponding to the MAC operation result from the second common voltage CALN and the first common voltage CALP. The output voltage V_{OUT} may be expressed as Equation 7.

$${V}_{OUT} = CALP - CALN = \frac{1}{N \times {2}^{M}} {\sum }_{j = 0}^{M - 1} {\sum }_{i = 0}^{N - 1} {V}_{i} {W}_{i , j} {2}^{j} = \frac{1}{N \times {2}^{M}} {\sum }_{i = 0}^{N - 1} {V}_{i} {W}_{i} \qquad [ Equation 7 ]$$

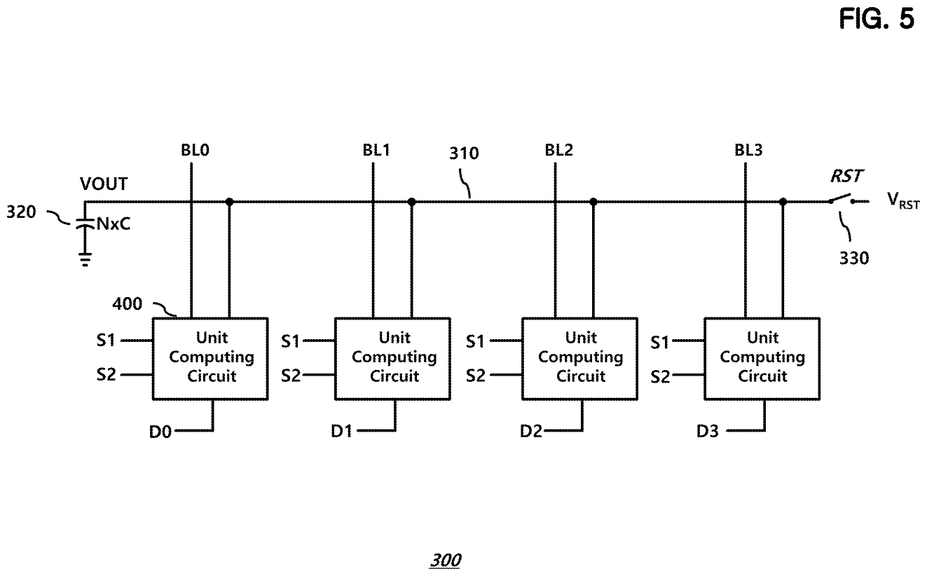

FIG. 5 illustrates a computing circuit 300 according to an embodiment of the present disclosure. The computing circuit 300 may be used as the computing circuit 100 shown in FIG. 1.

The computing circuit 300 includes a common line 310, a common capacitor 320, a reset switch 330, and a plurality of unit computing circuits 400.

In FIG. 5, it is assumed that a weight is 1 or −1. For example, when data stored in a memory cell is “0,” the weight corresponds to 1, and when the data stored in the memory cell is “1,” the weight corresponds to −1.

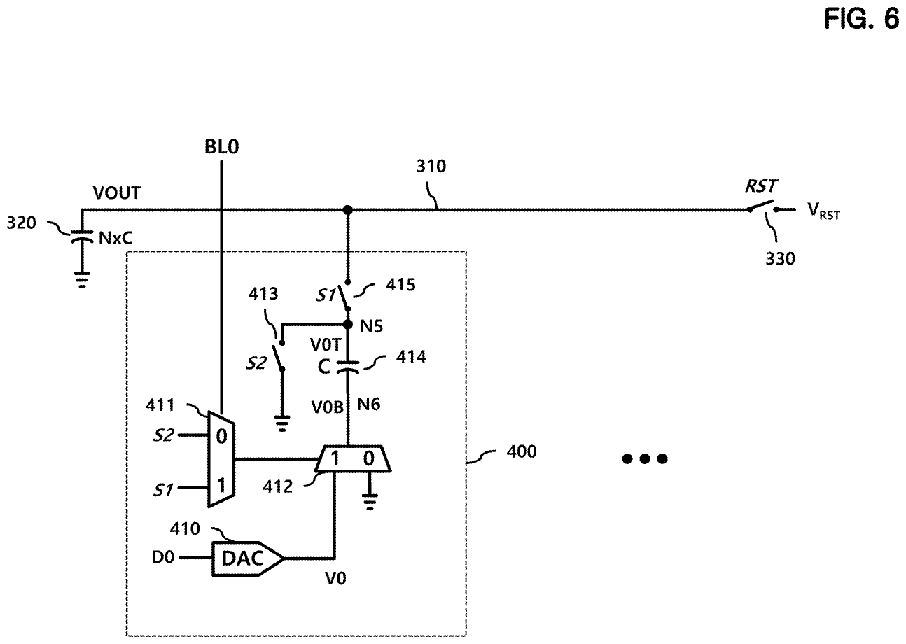

FIG. 6 illustrates the unit computing circuit 400 of FIG. 5 according to an embodiment of the present disclosure. For example, FIG. 6 illustrates the unit computing circuit 400 corresponding to the bit line BL0. The unit computing circuit 400 corresponding to another bit line may have the same configuration as shown in FIG. 6.

Referring to FIG. 6, the unit computing circuit 400 includes a digital-to-analog converter (DAC) 410 that converts the input data D0 into the input voltage V0, a first selection circuit 411 for selecting a first signal S1 or a second signal S2 according to a signal output from the bit line BL0, a second selection circuit 412 for selecting and outputting the input voltage V0 or the ground voltage GND to a sixth node N6 according to an output of the first selection circuit 411, a capacitor 414 connected between a fifth node N5 and the sixth node N6, a switch 413 connected between the fifth node N5 and the ground voltage node GND, and a switch 415 connected between the fifth node N5 and the common line 310.

The switch 415 is turned on or off in response to the first signal S1, and the switch 413 is turned on or off in response to the second signal S2.

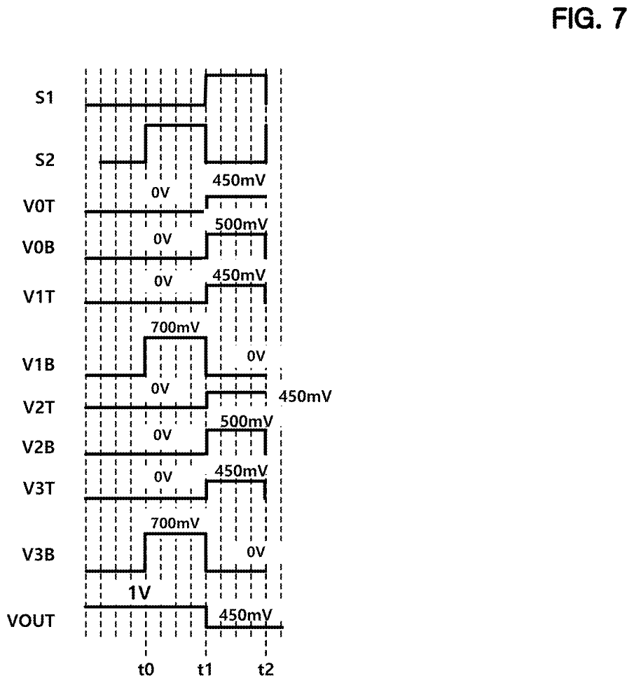

FIG. 7 is a timing diagram illustrating an operation of the computing circuit 300 of FIG. 5.

In FIG. 7, it is assumed that the input voltages V0 and V2 each have 500 mV and the input voltages V1 and V3 each have 700 mV.

In addition, it is assumed that the weights W0 and W2 are −1 and the weights W1 and W3 are +1, and that the weight “+1” corresponds to data “0” and the weight is “−1” corresponds to data “1.”

The computing circuit 300 sequentially performs a reset operation and a computing operation to perform a MAC operation on the weights W0, W1, W2, and W3 and the input data D0, D1, D2, and D3. Hereinafter, the reset operation may be referred to as a first operation and the computing operation may be referred to as a second operation.

The reset operation is performed in a time period of t0 to t1.

During the reset operation, the first signal S1 has the low level and the second signal S2 has the high level.

Accordingly, the switch 413 is turned on and the switch 415 is turned off, so that the fifth node N5 is disconnected from the common line 310 and connected to the ground voltage node GND through the switch 413. Therefore, voltages V0T to V3T have the ground voltage GND, i.e., 0V.

When the weight is +1, that is, when the signal output from the bit line BLi is “0,” the second signal S2 of the high level is selected, and thus the input voltage Vi is provided to the sixth node N6, i being 1 and 3. Therefore, voltages V1B and V3B have the input voltages V1 and V3, i.e., 700 mV, respectively.

When the weight is −1, that is, when the signal output from the bit line BLi is “1,” the first signal S1 of the low level is selected, and thus the ground voltage GND is provided to the sixth node N6. Therefore, voltages V0B and V2B respectively have the ground voltage GND.

That is, in the reset operation, if the weight is −1, the capacitor 414 is discharged, and if the weight is +1, the capacitor 414 is charged by the ground voltage GND provided to the fifth node N5 and the input voltage Vi provided to the sixth node N6. For example, for the weight W0, −1, corresponding to the bit line BL0, since both of the voltage V0T and the voltage V0B have the ground voltage GND, the corresponding capacitor 414 is discharged. On the other hand, for the weight W1, +1, corresponding to the bit line BL1, since the voltage V1T has the ground voltage GND and the voltage V1B has the input voltage V1, the corresponding capacitor 414 is charged by the input voltage V1.

During the reset operation, a reset signal RST becomes the high level and thus a reset voltage V_{RST} is applied to the common line 310.

An amount of charge Q_{RST} charged in the computing circuit 300 during the reset operation is as shown in Equation 8.

Q_{RST}=N×C×V_{RST}+C(0−V₁)+C(0−V₃) [Equation 8]

In Equation 8, N×C represents a capacitance of the common capacitor 320, and C represents a capacitance of the capacitor 414. The input voltages V1 and V3 are 700 mV and N is 4.

The computing operation is performed in a time period of t1 and t2.

During the computing operation, the first signal S1 has the high level and the second signal S2 has the low level.

Accordingly, the switch 415 is turned on and the fifth node N5 is connected to the common line 310.

When the weight is +1, that is, when the bit line signal BLi is “0,” the second signal S2 of the low level is selected, and thus the ground voltage GND is provided to the sixth node N6. Therefore, the voltages V1B and V3B respectively have the ground voltage, i.e., 0V.

When the weight is −1, that is, when the bit line signal BLi is “1,” the first signal S1 of the high level is selected, so that the input voltage Vi provided to the sixth node N6. Therefore, the voltages V0B and V2B have the input voltage, i.e., 500 mV.

An amount of charge Q_{MAC} charged in the computing circuit 300 during the computing operation is as shown in Equation 9.

Q_{MAC}=N×C×V_{OUT}+C(V_{OUT}−V₀)+CV_{OUT}+C(V_{OUT}−V₂)+CV_{OUT} [Equation 9]

In Equation 9, the input voltages V0 and V2 are 500 mV, and the output voltage V_{OUT} corresponds to the voltage of the common line 310 after the computing operation.

Since the amount of charge Q_{RST} is the same as the amount of charge Q_{MAC}, the output voltage V_{OUT} derived by applying the law of conservation of charge to Equations 8 and 9 is the same as Equation 10.

$${V}_{OUT} = \frac{{V}_{RST}}{2} + \frac{{V}_{0} - {V}_{1} + {V}_{2} - {V}_{3}}{8} \qquad [ Equation 10 ]$$

When the reset voltage V_{RST} is set to 1V, the output voltage V_{OUT} in FIG. 7 is 450 mV.

The output voltage V_{OUT} can be generalized as Equation 11.

$${V}_{OUT} = \frac{{V}_{RST}}{2} + \frac{1}{2 N} {\sum }_{i = 0}^{N - 1} {V}_{i} {W}_{i} \qquad [ Equation 11 ]$$

In Equation 11, Vᵢ represents a corresponding input voltage, and Wᵢ represents a corresponding weight.

Although various embodiments have been described for illustrative purposes, it will be apparent to those skilled in the art that various changes and modifications may be made to the described embodiments without departing from the spirit and scope of the disclosure as defined by the following claims.

What is claimed is:

1. A semiconductor device, comprising:
a memory cell array including a plurality of memory cells coupled between a plurality of word lines and a plurality of bit lines; and
a computing circuit configured to perform a multiplication and accumulation (MAC) operation using a plurality of input data and a plurality of weights respectively provided from the plurality of bit lines,
wherein one or more memory cells connected to each of the plurality of bit lines store a corresponding one of the plurality of weights, and the one or more memory cells store sign information of the corresponding weight.

2. The semiconductor device of claim 1, wherein the computing circuit includes:
a computing control circuit configured to generate sign signals based on the sign information of the plurality of weights;
a first common line connected to a first common capacitor;
a second common line connected to a second common capacitor; and
a plurality of unit computing circuits respectively corresponding to the plurality of bit lines, each of the plurality of unit computing circuits being provided with one of a plurality of bit line signals and one of the plurality of input data, the plurality of bit line signals respectively provided from the plurality of bit lines,
wherein, during a computing operation, each of the plurality of unit computing circuits is connected to the first common line and the second common line in response to a corresponding one of the sign signals.

3. The semiconductor device of claim 2, further comprising an output voltage generating circuit configured to generate a MAC operation result using a first voltage of the first common line and a second voltage of the second common line during the MAC operation.

4. The semiconductor device of claim 2, wherein each of the plurality of weights includes a sign bit and a magnitude bit, the sign bit corresponding to the sign information, and the magnitude bit is output from another memory cell that is different from a memory cell from which the sign bit is read, among the one or more memory cells, wherein when there are a plurality of magnitude bits, the plurality of magnitude bits are read sequentially from the least significant bit to the most significant bit from the one or more memory cells after the sign bit has been read.

5. The semiconductor device of claim 4, wherein the unit computing circuit includes:
a first capacitor being connected to the first common line when a sign bit of a corresponding weight represents a positive number and connected to the second common line when the sign bit represents a negative number;
a second capacitor being connected to the second common line when the sign bit represents the negative number and connected to the first common line when the sign bit represents the positive number;
a selection circuit configured to provide an input voltage corresponding to input data or a ground voltage to the first capacitor according to a value of the magnitude bit.

6. The semiconductor device of claim 5, wherein the unit computing circuit further includes a switch disconnecting the first capacitor from the first common line and the second common line during a reset operation, and
wherein the unit computing circuit performs the computing operation where the switch is turned on and the first capacitor is connected to the first common line or the second common line after the reset operation is completed and then the first capacitor is charged to the input voltage or the ground voltage, the MAC operation including the reset operation and the computing operation.

7. The semiconductor device of claim 5, wherein the unit computing circuit further includes a switch disconnecting the second capacitor from the first common line and the second common line during a reset operation, and
wherein the unit computing circuit performs the computing operation where the switch is turned on and the second capacitor is connected to the first common line or the second common line after the reset operation is completed and then the second capacitor is charged to the ground voltage.

8. The semiconductor device of claim 5, wherein the unit computing circuit further includes a digital-to-analog converter configured to convert the corresponding input data to the input voltage.

9. The semiconductor device of claim 1, wherein the computing circuit includes:
a common line coupled to a common capacitor;
a reset switch configured to provide a reset voltage to the common line during a first operation; and
a plurality of unit computing circuits each being provided with a bit line signal and input data, the plurality of unit computing circuits being disconnected from the common line during the first operation and coupled to the common line during a second operation following the first operation,
wherein the computing circuit performs the MAC operation with the plurality of input data and the plurality of weights by performing the first operation and the second operation, and
wherein each of the plurality of weights has a positive number or a negative number according to a bit line signal provided from a corresponding bit line.

10. The semiconductor device of claim 9, wherein each of the plurality of unit computing circuits includes:
a capacitor having a first terminal connected to the common line and a second terminal receiving a ground voltage or an input voltage corresponding to the input data;
a first switch disconnecting the capacitor from the common line during the first operation and connecting the capacitor to the common line during the second operation; and
a second switch providing the ground voltage to the first terminal of the capacitor during the first operation.

11. The semiconductor device of claim 10, wherein, when a corresponding weight has the positive number, the ground voltage is provided to the second terminal of the capacitor during the first operation and the input voltage is provided to the second terminal of the capacitor during the second operation, and
wherein, when the corresponding weight has the negative number, the input voltage is provided to the second terminal of the capacitor during the first operation and the ground voltage is provided to the second terminal of the capacitor during the second operation.

12. The semiconductor device of claim 10, wherein the positive number is +1, and the negative number is −1.
